(19) United States
(12) Patent Application Publication
(10) Pub. No.: US 2019/0089328 A1
(43) Pub. Date: Mar. 21, 2019

(54) SAW COMPONENT WITH REDUCED DISTURBANCES BY TRANSVERSAL AND SH MODES AND HF FILTER WITH SAW COMPONENT

(71) Applicant: SNAPTRACK, INC., San Diego, CA (US)

(72) Inventor: Quirin UNTERREITHMEIER, Munich (DE)

(21) Appl. No.: 16/085,461

(22) PCT Filed: Mar. 17, 2017
(86) PCT No.: PCT/US2017/023014

§ 371 Date: Sep. 14, 2018

(30) Foreign Application Priority Data
Mar. 18, 2016 (DE) 10 2016 105 118.7

(51) Int. Cl. H03H 9/02; H03H 9/145

(52) U.S. Cl. CPC H03H 9/02858; H03H 9/1457; H03H 9/1452

(57) ABSTRACT

A SAW component and an HF filter with a SAW component are specified, each with reduced disturbances by transversal modes and by SH modes. The SAW component comprises an active area with an internal area between two peripheral areas. The main mode of the SAW component has a lower velocity in the peripheral areas than in the internal area.

SAW component with reduced disturbances by transversal and SH modes and HF filter with SAW component.

The invention concerns SAW components and HF filters with such components. Disturbances caused by transversal modes and disturbances caused by SH modes in the components and in the filters respectively are reduced.

HF filter, e.g. bandpass filters or band-stop filters may be used in portable communication devices such as mobile phones in the front-end circuits. SAW transducers (SAW=surface acoustic wave) as parts of SAW components generally have a piezoelectric substrate and electrode fingers arranged on it that engage pectinately. Due to the piezoelectric effect, such transducers switch between HF signals and acoustic waves that can expand on the surface of the substrate. The transducers may be electro-acoustic resonators with a resonance and an anti-resonance frequency that are particularly determined by the center distance of adjacent electrode fingers. During the operation of a transducer, however, generally undesired wave modes are excited in addition to the desired wave modes; the former being loss channels for acoustic energy and increasing the insertion loss. The transducer function is disturbed in particular when the undesired wave modes generate resonances near the resonance and anti-resonance frequency. HF filters with SAW transducers then have an increased waviness in the passband or the blocking band and a distorted form of the band flanks.

The undesired modes include SH modes (SH mode=shear horizontal mode) with horizontally polarized shear waves and transversal modes that extend in transversal direction, i.e. orthogonally to the extension direction of the desired wave modes.

In order to decrease transversal modes, a component can be equipped with a transversal velocity profile as known, for example, from WO 2011/088904 A1 which promotes the formation of a so-called “piston” mode. This forms waveguide structures that disturb the creation of transversal modes.

Known measures to reduce disturbances by SH modes concern the reduction of the pole zero distance (PZD), e.g. by interconnecting the transducers with additional capacitive elements. This does not necessarily reduce the intensity of an SH mode. However, the distance of its frequency to the critical characteristic transducer frequencies is increased. This makes it possible, for example, to decrease the frequency of the anti-resonance of the transducer and thus remove it from the frequency of the SH mode.

Decreasing the pole zero distance for HF filters, however, leads to a reduction of the bandwidth that is obtainable so that this method can only be selected with sufficiently narrow frequency bands to be covered. Broader frequency bands, e.g. band 3, can then no longer be served.

There was therefore the desire for components in which disturbances by undesired wave modes are reduced. There was especially a desire for components that are less susceptible to disturbances from SH modes and that can serve broader frequency bands as part of HF filters.

For this purpose, the SAW component and the HF filter according to the main claims are stated. Dependent claims specify advantageous embodiments.

The SAW component comprises a piezoelectric substrate and an active area with engaging electrode fingers. The active area furthermore has two peripheral areas and an internal area. The internal area is arranged between the two peripheral areas. In the active area, a main mode is capable of propagation in the active area. The main mode has a velocity vᵢ in the internal area. In the peripheral areas, the main mode has a velocity vᵣ that is less than vᵢ by 100 m/s to 200 m/s.

As a piezoelectric substrate, materials such as lithium niobate (LiNbO₃), lithium tantalate (LiTaO₃) and quartz are suitable. The active area is arranged on the surface of the piezoelectric substrate. Especially the interacting electrode fingers that may each be switched to a busbar are arranged on the surface of the piezoelectric substrate. The active area of the component is that area in which the electrode fingers of contrarily polarized electrodes overlap and are modified between acoustic waves and HF signals. The peripheral areas extend along the propagation direction of the acoustic waves, the longitudinal direction. The electrode fingers extend along the transversal direction that is aligned orthogonally to the longitudinal direction.

It is possible that the peripheral areas cover the respective free ends of the fingers that are not directly connected to a busbar.

It occurs in a SAW component in this configuration that the main mode may be designed almost completely as a so-called piston mode. Transversal disturbances are massively suppressed. SH modes have such a low coupling that they can practically be neglected.

The configuration is furthermore very suitable to use in filters that work with a broad band. Furthermore, the configuration allows a simple manufacturing due to its high homogeneity of the layer structures without having a considerably increased susceptibility for errors during the production process.

It is therefore possible that the peripheral areas extend along the propagation direction of the main mode.

The peripheral areas may have a strip-shaped extension.

It is possible that there is one weighting strip each per peripheral area arranged in the peripheral areas. The respective weighting strip increases the mass distribution in the peripheral areas.

Due to the increased mass distribution, one obtains a transversal velocity profile that is able to sufficiently suppress a transversal excitation and at the same time reduces the coupling for SH modes.

It is possible that the weighting strips comprise a metal as their main component or consist of a metal that is selected from copper (Cu), silver (Ag), gold (Au), tungsten (W) and titanium (Ti).

Basically, any element or any compound is suited that stand up against the usual materials on the top surface of a SAW component, e.g. a passivation material or a material to reduce the temperature-related frequency variation.

In addition to metals, heavy dielectric materials, e.g. oxides of the above-mentioned heavy metals are suitable as material for the weighting strips.

The periodicity of the electrode fingers along the longitudinal direction is expressed by the so-called pitch p. The pitch p in this is the locally defined average distance of the finger center or the left or right finger edges of adjacent electrode fingers. The pitch p corresponds therefore substantially to half the wavelength λ/2 of the main mode that may extend in the active area.

The weighting strips may have a thickness d that is given in units of pitch p and are, for example, between 0.024 and 0.196: 0.02≤d/p≤0.04.

It is possible that a dielectric layer is positioned between the weighting strip and the substrate and/or the weighting strip and the electrode fingers. Especially when the weighting strips consist of a conducting material, the dielectric layer forms an electrical insulation between electrode fingers arranged next to each other having a different polarization and the weighting strips.

The dielectric layer may comprise a silicon oxide, e.g. SiO₂, a germanium oxide, e.g. GeO or GeO₂, or a tellurium oxide, e.g. TeO or TeO₂ or consist of these.

The propagation of the acoustic waves and thus the acoustic and electrical features of SAW components with the respective design are complex. In order to sufficiently suppress both transversal disturbances and SH modes, the metallization ratio η may be selected accordingly, e.g. 0.39≤η≤0.65.

It is possible that the SAW component additionally features an upper dielectric layer above the above-mentioned dielectric layer and/or above the weighting strips.

It is possible that the upper dielectric layer comprises a silicon oxide, e.g. iO₂ or a germanium oxide, e.g. GeO or GeO2.

It is possible that the dielectric layer has a thickness d₁ and forms a common layer with a thickness of d₁+d₂ together with the upper dielectric layer with the thickness d₂ which—standardized to the pitch p—is 0.66.

It is possible that the dielectric layer has a thickness d₁, the upper dielectric layer has the thickness d₂, the weighting strip comprises Ti and has a thickness d_{BS} and (d₁+d₂+d_{BS})/p=0.66.

It is possible that the SAW component additionally features a dielectric top layer that serves, for example, as a passivation layer.

The dielectric top layer may comprise a silicon nitride or consist of a silicon nitride.

It is possible that the dielectric top layer has a thickness d with 40 nm≤d≤120 nm.

It is possible that the main mode is a Rayleigh mode and the velocity in the internal area vᵢ is between 3,460 m/s and 3,600 m/s.

The velocity vᵢ in the internal area here may also depend on the thickness of the dielectric layer on the top surface of the piezoelectric substrate and below the weighting strip. As an example for weighting strips of copper with a thickness of 0.06 μm, the velocity vᵢ at a thickness of the dielectric layer of 0.0 μm may be 3,420 m/s.

As an example for weighting strips of copper with a thickness of 0.1 μm, the velocity vᵢ at a thickness of the dielectric layer of 0.5 μm may be 3,390 m/s.

It is possible that the relative electro acoustic coupling kᵣₑₗ=k_{RB}/k_{IB}, namely the coupling in the peripheral area k_{RB} standardized to the coupling in the internal area k_{IB}, may be greater or equal to 0.90, preferably 1.0.

The following table shows the preferred parameter combinations. The material of the electrode fingers is copper. The material of the weighting strips Mat_{BS} is either copper or titanium. The thickness d(EF) of the electrode fingers is given in nm. The thickness d(DL) of the dielectric layer is given in μm. The thickness d(BS) of the weighting strip is given in μm. The pitch p is given in μm. The metallization ratio η is a number without a unit. The relative excitation strength (excitation strength k in the peripheral area/excitation strength in the internal area) is also a number without a unit. Δv states the reduction of the velocity in the peripheral area compared to the velocity in the internal area in m/s. d(BS)/p is the thickness of the weighting strip per pitch p.

| Mat_{BS} | D(EF) | d(DL) | d(BS) | p | η | kᵣₑₗ | Δv | d(BS)/p |
|---|---|---|---|---|---|---|---|---|
| Cu | 335 | 0.6 | 0.06 | 2.05 | 0.6 | 0.9295 | 103 | 0.029268293 |
| Cu | 335 | 0.6 | 0.07 | 2.05 | 0.62 | 0.923 | 118 | 0.034146341 |
| Cu | 335 | 0.5 | 0.08 | 2.05 | 0.53 | 0.908 | 106 | 0.03902439 |
| Cu | 335 | 0.5 | 0.09 | 2.05 | 0.535 | 0.905 | 119 | 0.043902439 |
| Cu | 335 | 0.5 | 0.1 | 2.05 | 0.54 | 0.9025 | 131 | 0.048780488 |
| Cu | 355 | 0.7 | 0.05 | 2.05 | 0.585 | 0.945 | 106 | 0.024390244 |
| Cu | 355 | 0.6 | 0.06 | 2.05 | 0.54 | 0.9352 | 104 | 0.029268293 |
| Cu | 355 | 0.7 | 0.06 | 2.05 | 0.615 | 0.935 | 124 | 0.029268293 |
| Cu | 355 | 0.6 | 0.07 | 2.05 | 0.555 | 0.9305 | 119.5 | 0.034146341 |
| Cu | 355 | 0.6 | 0.08 | 2.05 | 0.57 | 0.925 | 134.5 | 0.03902439 |
| Cu | 355 | 0.6 | 0.09 | 2.05 | 0.58 | 0.919 | 149 | 0.043902439 |
| Cu | 355 | 0.6 | 0.1 | 2.05 | 0.595 | 0.913 | 163 | 0.048780488 |
| Ti | 355 | 0.8 | 0.2 | 2.05 | 0.58 | 0.96 | 115 | 0.097560976 |
| Ti | 355 | 0.6 | 0.3 | 2.05 | 0.5 | 0.946 | 125 | 0.146341463 |
| Ti | 355 | 0.5 | 0.4 | 2.05 | 0.445 | 0.9115 | 140 | 0.195121951 |

The metallization ratio η may deviate by ±0.15. The relative coupling strength kᵣₑₗ may deviate by ±0.04. The difference in velocity may deviate by ±20 m/s.

It is possible that the electrode fingers comprise Cu or Ti, and for their thickness d standardized to the pitch p, the following applies: 0.15≤d(EF)/p≤0.19.

It is possible that the electrode fingers comprise Cu or Ti, and for the thickness of the dielectric layer, the following applies: 0.5 μm≤d(DL)≤0.8 μm.

It is possible that the electrode fingers comprise Cu, and for the thickness of the dielectric layer, the following applies: 0.23≤d(DL)/p≤0.42.

It is possible that the electrode fingers comprise Cu, and for the thickness of the weighting strip, the following applies: 0.05 μm≤d(BS)≤0.1 μm.

It is possible that the electrode fingers comprise Cu, and for the thickness of the weighting strip, the following applies: 0.02≤d(BS)/p≤0.05.

It is possible that the electrode fingers comprise Cu and the weighting strips are made of Ti, and for the thickness of the weighting strip, the following applies: 0.2 μm≤dd(BS)≤0.4 μm.

It is possible that the electrode fingers comprise Ti, and for the thickness of the weighting strip, the following applies: 0.09≤d(BS)/p≤0.21.

For Cu electrode fingers with a thickness of 335 nm and a weighting strip made of Cu, the metallization ratio η may have the following dependency on the thickness of the weighting strip d(BS) in μm and on the thickness of the dielectric layer d(DL) in μm: η=0.0184+0.670 d(BS)+0.917 d(DL).

For Cu electrode fingers with a thickness of 355 nm and a weighting strip made of Cu, the metallization ratio η may have the following dependency on the thickness of the weighting strip d(BS) in μm and on the thickness of the dielectric layer d(DL) in μm: η=0.0358+1.47 d(BS)+0.695 d(DL).

For Cu electrode fingers with a thickness of 355 nm and a weighting strip made of Ti, the metallization ratio η may have the following dependency on the thickness of the weighting strip d(BS) in μm and on the thickness of the dielectric layer d(DL) in μm: η=0.500+0.356 d(BS)+0.194 d(DL).

For Cu electrode fingers with a thickness of 335 nm and a weighting strip made of Cu, the velocity reduction ratio Δv in m/s may have the following dependency on the thickness of the weighting strip d(BS) in μm and on the thickness of the dielectric layer d(DL) in μm: η=140+1280 d(BS)+237 d(DL).

For Cu electrode fingers with a thickness of 355 nm and a weighting strip made of Cu, the velocity reduction ratio Δv in m/s may have the following dependency on the thickness of the weighting strip d(BS) in μm and on the thickness of the dielectric layer d(DL) in μm: Δv=−97.1+1500 d(BS)+186 d(DL).

For Cu electrode fingers with a thickness of 355 nm and a weighting strip made of Ti, the velocity reduction ratio Δv in m/s may have the following dependency on the thickness of the weighting strip d(BS) in μm and on the thickness of the dielectric layer d(DL) in μm: η=81.4+138 d(BS)+9.83 d(DL).

For electrode fingers made of Cu with a thickness of 335 nm and a weighting strip made of Cu, an adaptation of the metallization ratio η to pitch deviations (in μm) may have the following dependencies: Δη=−0.089(p−2.05).

For electrode fingers made of Cu with a thickness of 355 nm and a weighting strip made of Cu, an adaptation of the metallization ratio η to pitch deviations (in μm) may have the following dependencies: Δη=−0.113(p−2.05).

For electrode fingers made of Cu with a thickness of 355 nm and a weighting strip made of Ti, an adaptation of the metalization ratio η to pitch deviations (in μm) may have the following dependencies: Δη=−0.366(p−2.05).

For electrode fingers made of Cu with a thickness of 335 nm and weighting strips made of Cu, the velocity reduction Δv in m/s may have the following dependency of the pitch p in μm: Δv=147-15.0 p.

For electrode fingers made of Cu with a thickness of 355 nm and weighting strips made of Cu, the velocity reduction Δv in m/s may have the following dependency of the pitch p in μm: Δv=168−18.7 p.

For electrode fingers made of Cu with a thickness of 355 nm and weighting strips made of Ti, the velocity reduction Δv in m/s may have the following dependency of the pitch p in μm: Δv=382−124 p.

It is possible that the electrode fingers comprise Cu, and for the thickness of the dielectric layer, the following applies: 0.23≤d(DL)/p≤0.42.

It is possible that the electrode fingers comprise Cu, and for the thickness of the weighting strip, the following applies: 0.02≤d(BS)/p≤0.05.

It is possible that the electrode fingers comprise Ti, and for the thickness of the weighting strip, the following applies: 0.09≤d(BS)/p≤0.21.

An HF filter may at least comprise an SAW component with the respective design with reduced disturbances due to transversal and SH modes.

The functionality and examples that serve to illustrate the design of the layer stacks become apparent in the schematic figures.

Shown are:

FIG. 1: top view of a SAW component with peripheral areas in the active area,

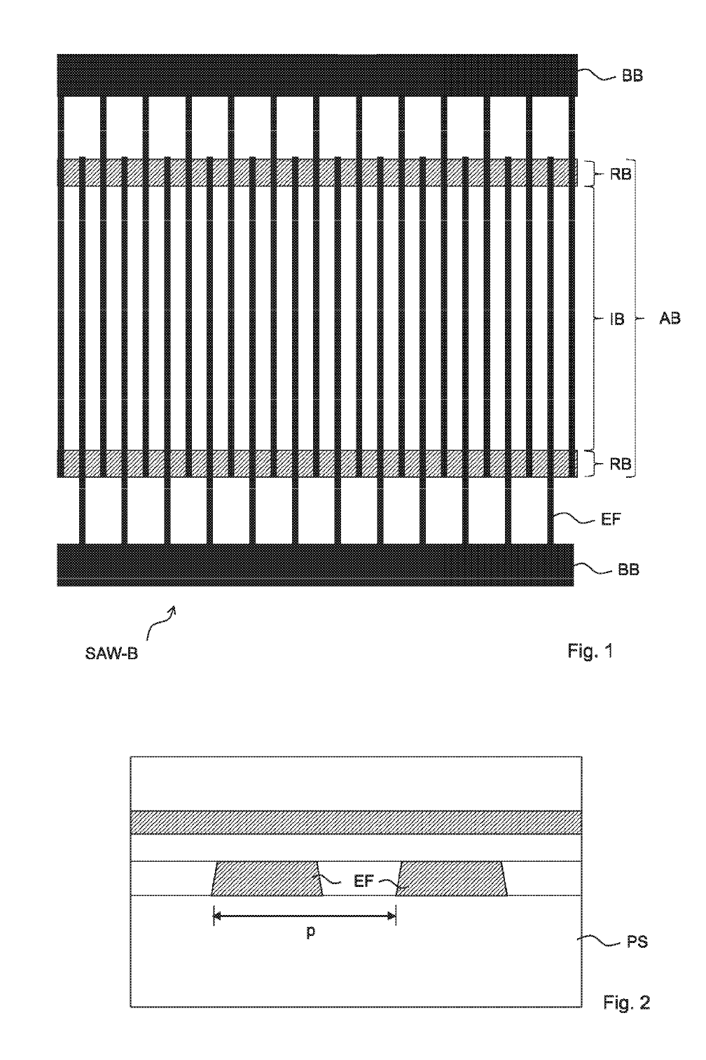

FIG. 2: cross section through a corresponding component and the definition of the pitch p,

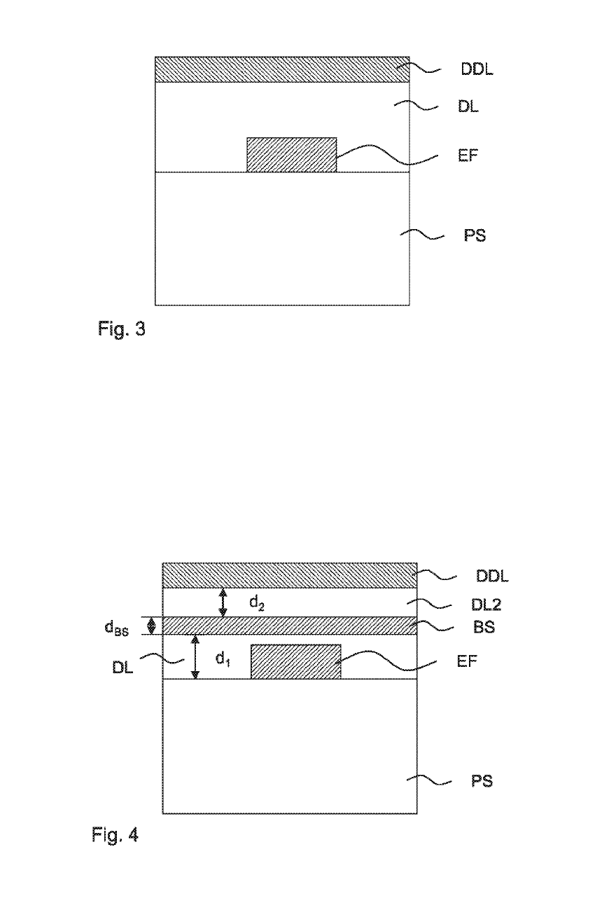

FIG. 3: cross section through a component with an electrode finger embedded in a dielectric layer,

FIG. 4: cross section through an additional component with weighting strips,

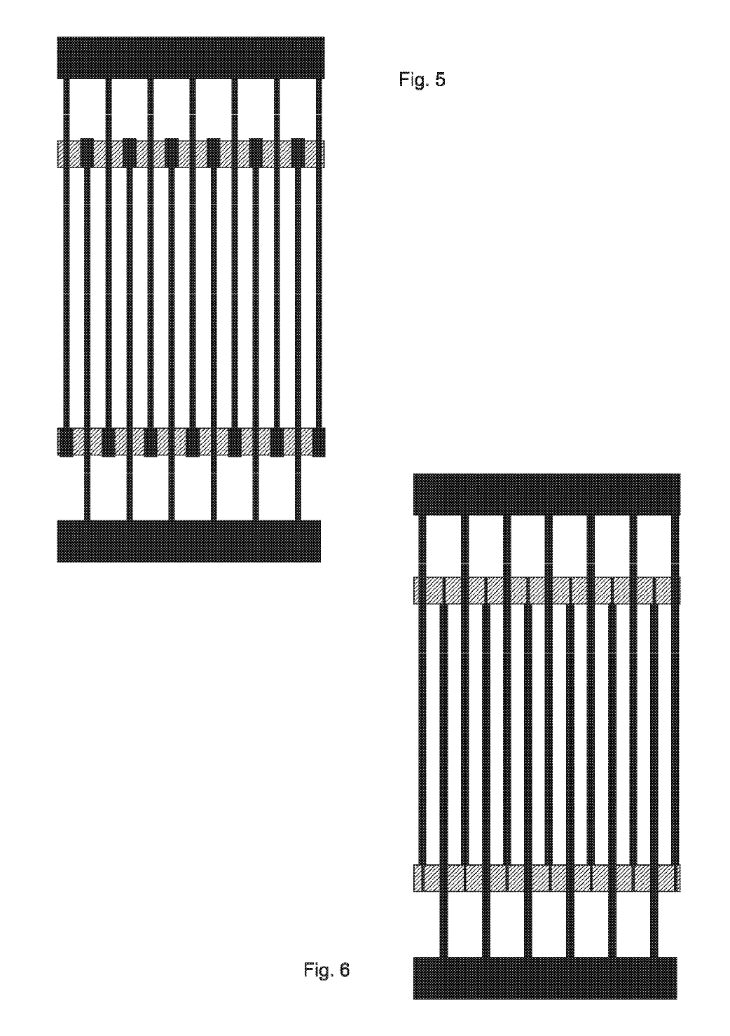

FIG. 5: widened electrode fingers in the peripheral area,

FIG. 6: narrower electrode fingers in the peripheral area,

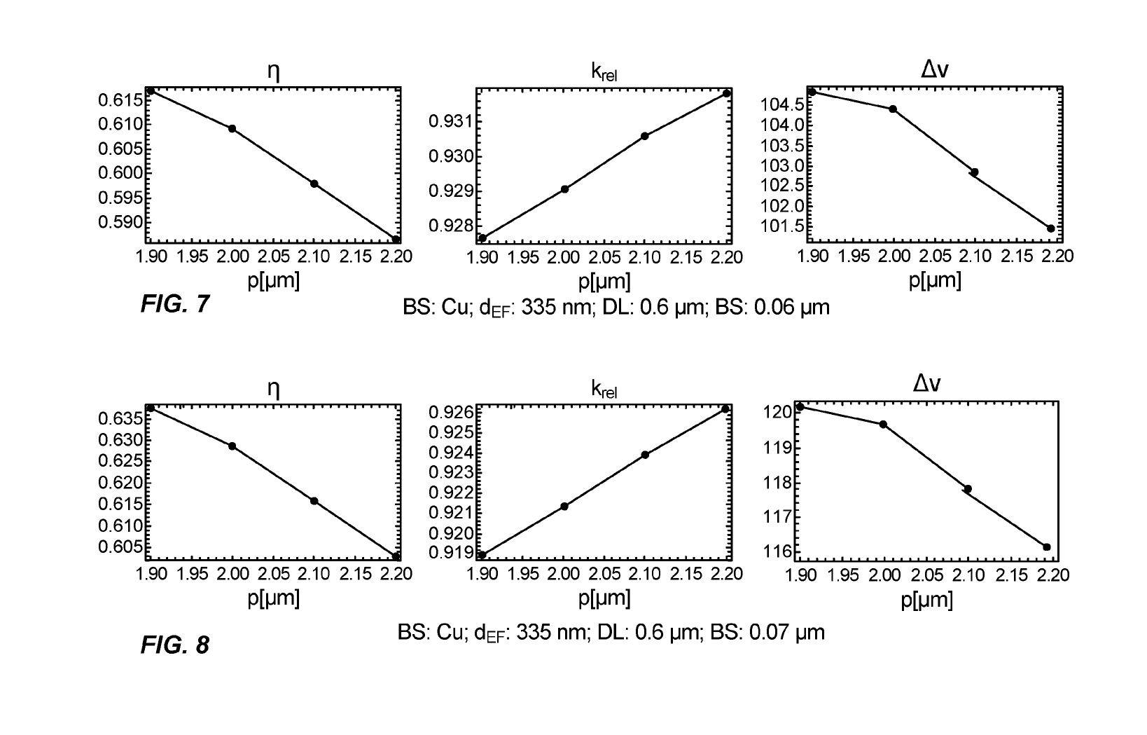

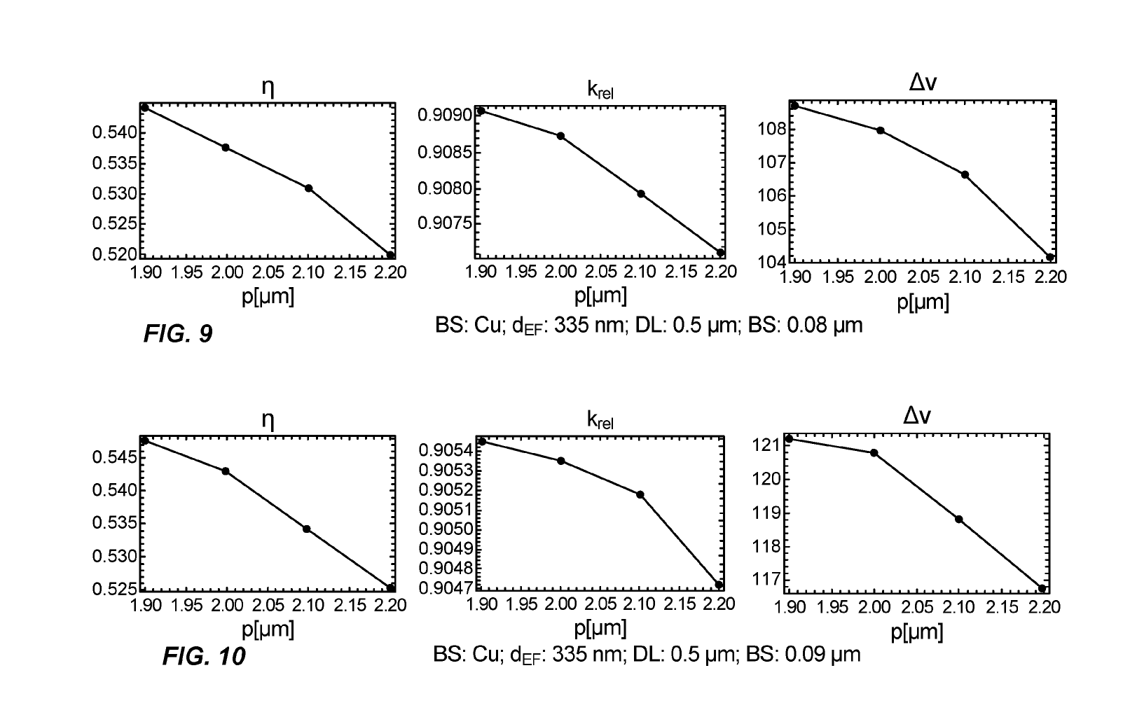

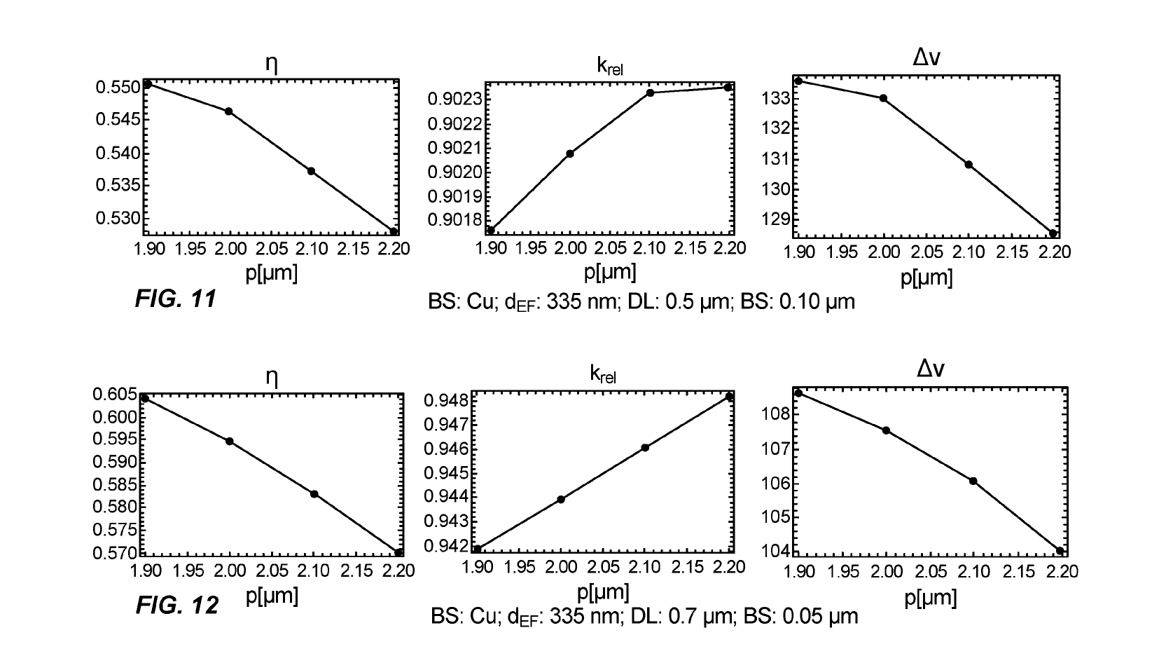

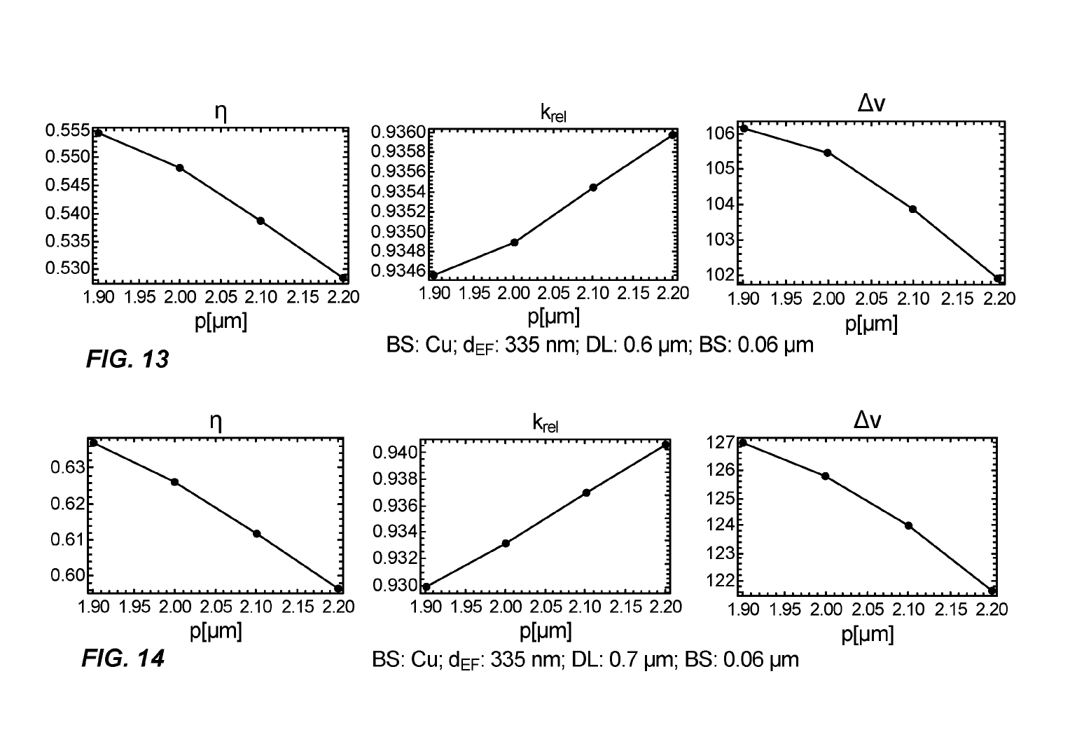

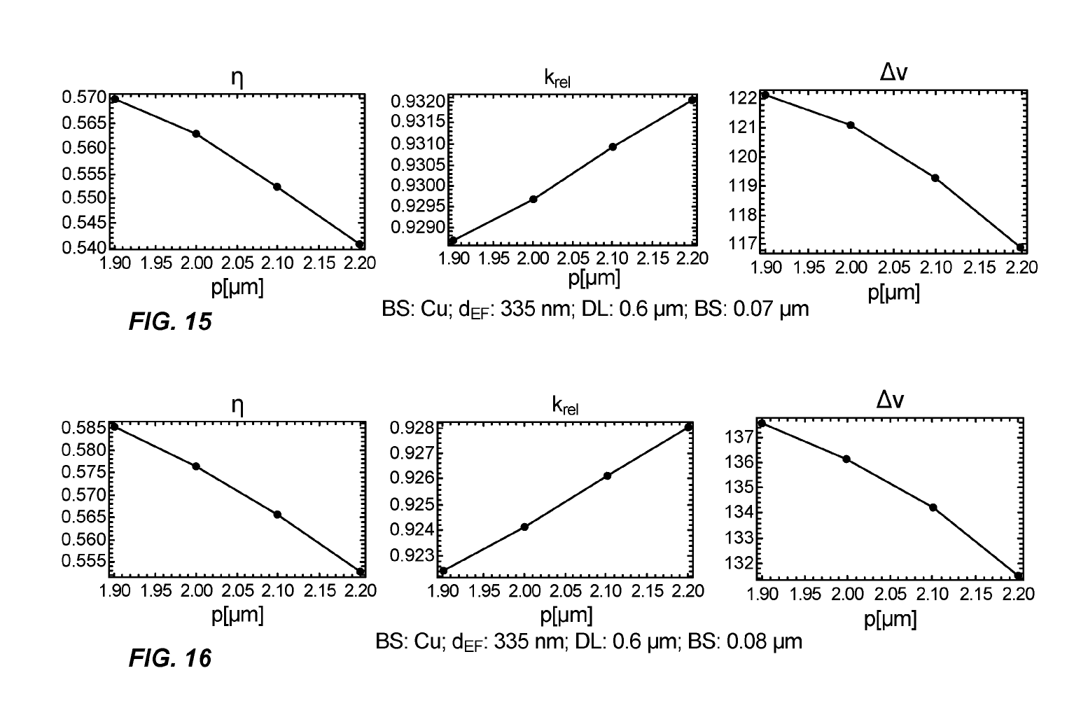

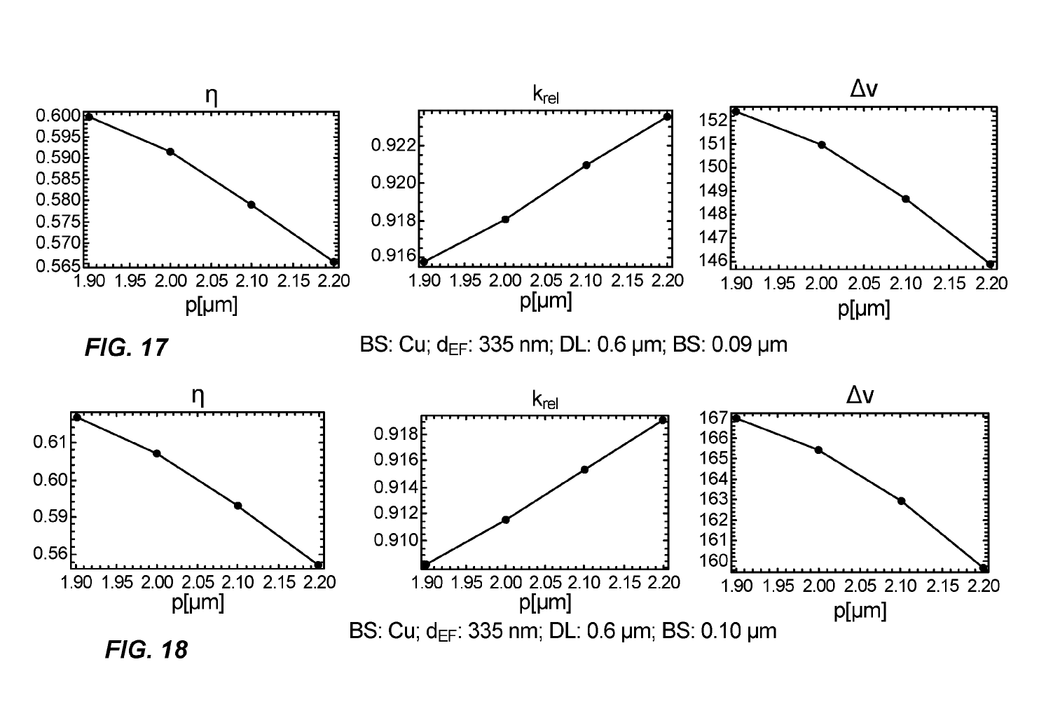

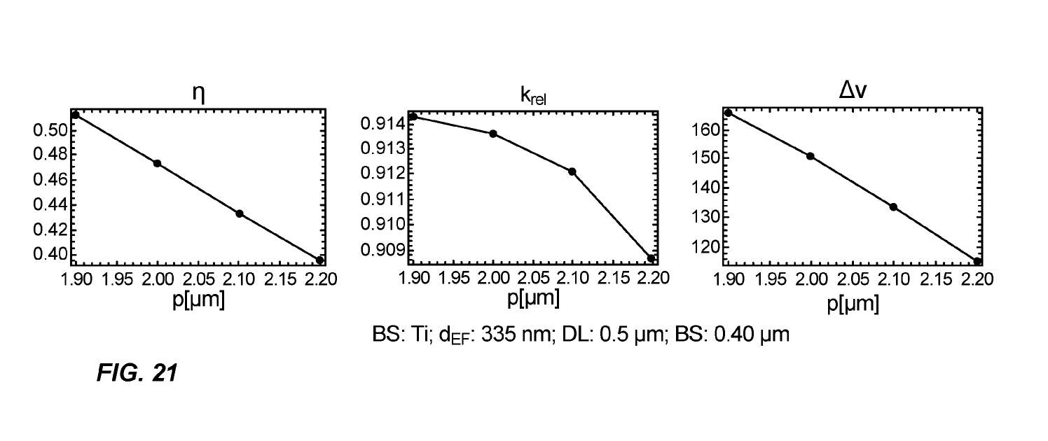

FIGS. 7-21: advantageous parameters.

FIG. 1 shows a top view of the electrode structure of a SAW component SAW-B, in which electrode fingers EF are respectively arranged next to each other in longitudinal direction and themselves extend along the transversal direction. In this, the electrode fingers EF are alternately switched to one of two busbars BB respectively. The area in which the electrode fingers of opposite busbars overlap is the active area AB where the switch between HF signals of the desired frequency and acoustic waves takes place. For this, the active area AB has peripheral areas RB and an internal area IB. Substantially, the peripheral areas cover the ends of the electrode fingers that are not directly linked to a busbar, the so-called free finger ends. The internal area IB is arranged between the peripheral areas.

By reducing the velocity vᵣ in the peripheral areas relatively to the velocity vᵢ of the main modes in the internal area IB, the result is a transversal velocity profile that firstly suppresses a transversal mode and secondly reduces the electro-acoustic coupling for SH modes to such an extent that the component is even ideal for use in filters working in broadband mode.

FIG. 2 shows a cross section through a layer structure to illustrate the definition of the pitch p: Electrode fingers EF are arranged on the piezoelectric substrate PS. The distance from the left or right finger edges to the adjacent electrode fingers is the pitch p.

FIG. 3 shows a cross section through a layer stack in the internal area TB with electrode fingers EF that are arranged on the piezoelectric substrate PS. On the top surface of the piezoelectric substrate PS and/or the electrode finger EF, a dielectric material of the dielectric layer DL has been arranged. The material of the dielectric layer DL may have a thermal expansion coefficient that is selected in such a way that the temperature variation of the frequencies at a given expansion coefficient of the substrate and the finger material is selected in such a way that the temperature variation of the entire layer stack is reduced or decreased.

A dielectric top layer DDL is arranged on the dielectric layer DL that may serve as a passivation layer.

Silicon oxide is a possible material for the dielectric layer. Silicon nitride is a possible material for the dielectric top layer.

FIG. 4 shows a cross section through a layer stack at the level of the peripheral area RB, wherein the weighting strip BS is arranged on material of the dielectric layer DL. Thus, the material of the dielectric layer not only has the task of reducing a temperature variation of the frequencies. The material of the dielectric layer DL rather has the task preventing the material of the weighting strip BS from short-circuiting with the electrode fingers that are switched to different busbars.

An upper dielectric layer DL2 is arranged above the weighting strip, and the dielectric top layer DDL in turn is arranged on said upper dielectric layer.

FIG. 5 schematically shows that the finger widths (and thus the metallization ratio rᵢ) in the peripheral area may be lower than the finger widths in the internal area.

FIG. 6 shows in an analogous manner that the finger widths in the internal area may be smaller than in the peripheral area.

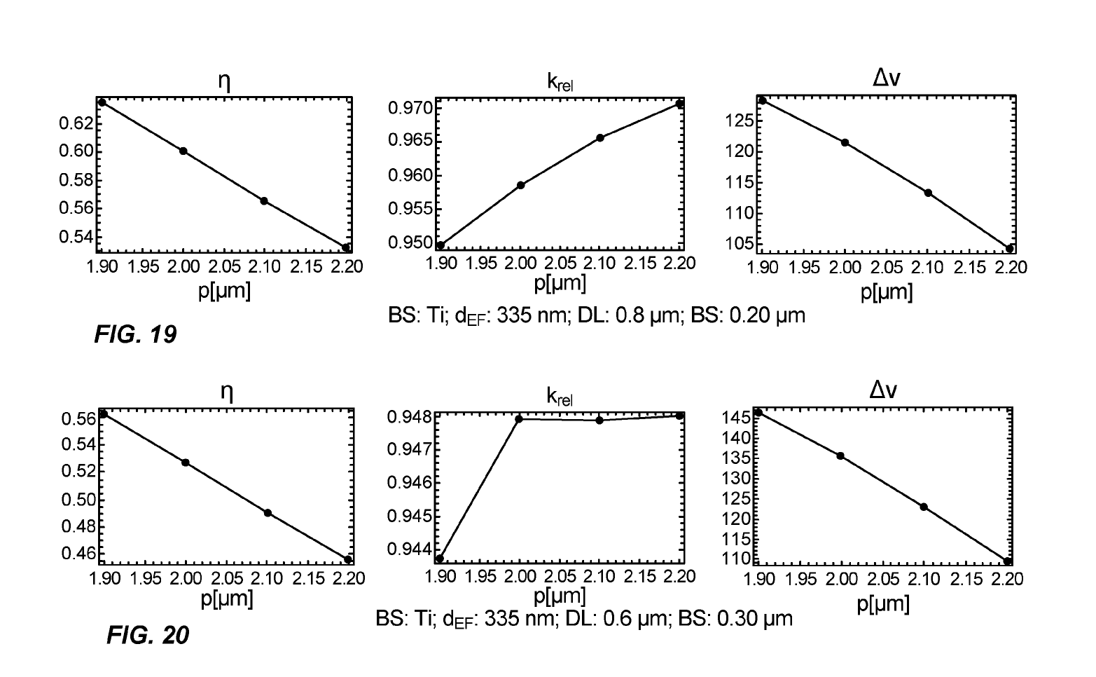

FIGS. 7 to 21 show advantageous parameters of the SAW component. FIGS. 7 to 18 show values for a transducer with electrode fingers and weighting strips made of copper. FIGS. 19 to 21 show values for a transducer with electrode fingers made of Cu and weighting strips made of titanium.

FIGS. 7 to 11 show values for a transducer whose electrode fingers have a thickness of 335 nm. FIGS. 12 to 18 show values for a transducer whose electrode fingers have a thickness of 355 nm. FIGS. 19 to 21 show values for a transducer whose electrode fingers have a thickness of 335 nm. The indicated values for the thickness of the dielectric layer DL, the thickness of the weighting strip BS, the metallization ratio η that is advantageous for a certain pitch p (e.g. p=2.05±0.15), the relative coupling strength kᵣₑₗ that is advantageous for a certain pitch p and the advantageous reduction of the velocity are summarily illustrated in the table shown.

If the pitch p deviates from 2.05, the respective optimized values can be taken from the charts.

### LIST OF REFERENCE CHARACTERS

AB: active area

BB: busbar

d: thickness of the dielectric layer

DDL: dielectric top layer

DL: dielectric layer

DL2: upper dielectric layer

EF: electrode finger

IB: internal area

p: pitch

PS: piezoelectric substrate

RB: peripheral area

SAW-B: SAW component

v, vᵢ, vᵣ: propagation velocity

w: width of the electrode fingers

k²: coupling strength

1. A surface acoustic wave (SAW) component (SAW-B) with reduced disturbances by transversal and sheer horizontal (SH) modes, comprising:
a piezoelectric substrate (PS); and
an active area (AB) with interlacing electrode fingers (EF), the active area (AB) having an internal area (IB) and two peripheral areas (RB), the internal area (AB) being arranged between the two peripheral areas (RB), wherein:
a main mode is capable of propagation in the active area (AB);
a thickness of the interlacing electrode fingers (EF) in the peripheral areas is less than a thickness of the interlacing electrode fingers (EF) in the internal area (IB); and
one weighting strip (BS) is arranged in each of the peripheral areas (RB).

2. The SAW component according to the previous claim, wherein the peripheral areas (RB) extend along the propagation area of the main mode.

3. (canceled)

4. The SAW component according to one of the previous claims, wherein a metallization ratio η in the peripheral areas (RB) deviates from a metallization ratio η in the internal area (IB).

5. The SAW component according to the previous claim, wherein the weighting strips (BS) comprise a material that is selected from: copper (Cu), silver (Ag), gold (Au), tungsten (W), and titanium (Ti).

6. The SAW component according to one of the 2 previous claims, wherein the weighting strips (BS) have a thickness d in units of a pitch p, wherein d is within the range: 0.024≤d/p≤0.196, the pitch being a distance between a center of two adjacent electrodes of the interlacing electrode fingers (EF).

7. The SAW component according to one of the 3 previous claims, wherein a dielectric layer is arranged between the weighting strips (BS) and a substrate (SU).

8. The SAW component according to the previous claim, wherein the dielectric layer (DL) comprises a silicon oxide, a germanium oxide or a tellurium oxide.

9. The SAW component according to any of the previous claims, wherein the metallization ratio η is within the range: 0.39≤η≤0.66.

10. The SAW component according to one of the 3 previous claims, further comprising an upper dielectric layer (DL2) disposed above the dielectric layer.

11. The SAW component according to the previous claim, wherein the upper dielectric layer (DL2) comprises a silicon oxide, a germanium oxide.

12. The SAW component according to one of the 2 previous claims, wherein the dielectric layer (DL) has a thickness d₁, the upper dielectric layer (DL2) has the thickness d₂ and (d₁+d₂)/p=0.65.

13. The SAW component according to one of the 3 previous claims, wherein the dielectric layer (DL) has the thickness d₁, the upper dielectric layer (DL2) has the thickness d₂, the weighting strip (BS) comprises Ti and has a thickness d_{BS} and (d₁+d₂+d_{BS})/p=0.66, wherein p refers to a pitch, the pitch being a distance between a center of two adjacent electrodes of the interlacing electrode fingers (EF).

14. The SAW component according to one of the 4 previous claims, furthermore comprising a dielectric top layer (DDL) being disposed above the upper dielectric layer (DL2).

15. The SAW component according to the previous claims, wherein the dielectric top layer (DDL) comprises a silicon nitride.

16. The SAW component according to one of the 2 previous claims, wherein the dielectric top layer (DDL) has a thickness d that is within the range: 40 nm≤d≤120 nm.

17. The SAW component according to one of the previous claims, wherein the main mode is a Rayleigh mode, and wherein 3460 m/s≤vᵢ≤3600 m/s, wherein vᵢ is a velocity of the main mode.

18. (canceled)

19. The SAW component according to one of the previous claims, wherein the electrode fingers (EF) comprise Cu, and wherein a thickness d(EF) of electrode fingers (EF) is within the range: 0.15≤d(EF)/p≤0.19 nm, wherein p refers to a pitch, the pitch being a distance between a center of two adjacent electrodes of the interlacing electrode fingers (EF).

20. The SAW component according to one of the previous claims, wherein the electrode fingers (EF) comprise Cu, and wherein a thickness d(DL) of the dielectric layer (DL) is within the range: 0.23≤d(DL)/p≤0.42.

21. The SAW component according to one of the previous claims, wherein the electrode fingers (EF) comprise Cu, and wherein a thickness d(BS) of the weighting strip (BS) is within the range: 0.02≤d(BS)/p≤0.05, wherein p refers to a pitch, the pitch being a distance between a center of two adjacent electrodes of the interlacing electrode fingers (EF).

22. The SAW component according to one of the previous claims, wherein the electrode fingers (EF) comprise Ti, and wherein a thickness d(BS) of the weighting strip (BS) is within the range: 0.09≤d(BS)/p≤0.21, wherein p refers to a pitch, the pitch being a distance between a center of two adjacent electrodes of the interlacing electrode fingers (EF).

23. A HF filter with the SAW component (SAW-B) according to one of the previous claims.
